(19) United States
(12) Patent Application Publication
(10) Pub. No.: US 2024/0371721 A1
(43) Pub. Date: Nov. 7, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yi-Min FU, Taichung City (TW); Chi-Ching HO, Taichung City (TW); Chao-Chiang PU, Taichung City (TW); Yu-Po WANG, Taichung City (TW)

(73) Assignee: SILICONWARE PRECISION INDUSTRIES CO., LTD., Taichung City (TW)

(21) Appl. No.: 18/360,269

(22) Filed: Jul. 27, 2023

(30) Foreign Application Priority Data
May 4, 2023 (TW) 112116629

(51) Int. Cl. H01L 23/367; H01L 23/00; H01L 23/373; H01L 23/42

(52) U.S. Cl. CPC H01L 23/3675; H01L 23/373; H01L 23/42; H01L 24/16; H01L 24/81; H01L 2224/16227; H01L 2224/81801

(57) ABSTRACT

An electronic package and a manufacturing method thereof are provided, in which a heat sink with an opening is disposed on an electronic component of a carrier structure, a heat dissipation material is formed in the opening, and a heat dissipation lid is disposed on the opening to cover the heat dissipation material, such that the problem of insufficient heat dissipation due to the loss of the heat dissipation material can be prevented from occurring to the electronic component.

### BACKGROUND

### 1. Technical Field

The present disclosure relates to a packaging process, and more particularly, to an electronic package with a heat dissipation structure and manufacturing method thereof.

### 2. Description of Related Art

With the improvement of the function and processing speed of electronic products, semiconductor chips, which are the core components of electronic products, need to have higher density electronic components and electronic circuits, so the semiconductor chip will generate a larger amount of heat energy during operation. Furthermore, since the conventional packaging colloid covering the semiconductor chip is made of a poor heat transfer material with a thermal conductivity of merely 0.8 W·m⁻¹·k⁻¹ (i.e., the heat dissipation efficiency is poor), whereby it will cause damage to the semiconductor chip and product reliability problems when the heat generated by the semiconductor chip cannot be dissipated effectively.

Therefore, in order to rapidly dissipate heat to the outside, a heat sink or a heat spreader is usually configured in the semiconductor package in the industry. The heat sink is usually bonded to the back of the semiconductor chip via the heat dissipation glue (such as thermal interface material [TIM]), so that the heat generated by the semiconductor chip is dissipated by the heat dissipation glue and the heat sink. Moreover, a top surface of the heat sink is usually exposed from the packaging colloid or directly exposed to the atmosphere to obtain a better heat dissipation effect.

As shown in FIG. 1, in a conventional semiconductor package 1, a semiconductor chip 11 is flip-chip disposed (i.e., via conductive bumps 110 and an underfill 111) on a packaging substrate 10 having a circuit layer 100 with an active surface 11a of the semiconductor chip 11, a heat sink 13 is then bonded onto an inactive surface 11b of the semiconductor chip 11 via a TIM layer 12 with a top sheet 130 of the heat sink 13, and supporting legs 131 of the heat sink 13 are erected on the packaging substrate 10 via an adhesive layer 14.

During the operation, the heat energy generated by the semiconductor chip 11 is transferred to the top sheet 130 of the heat sink 13 via the inactive surface 11b and the TIM layer 12 to dissipate heat to the outside of the semiconductor package 1.

Moreover, in the industry, in order to cooperate with the development trend of electronic products towards multi-contact (I/O), large-dimension packaging specifications, large area and high heat dissipation, fluid heat dissipation material such as liquid metal is used to make the TIM layer 12 so as to replace the conventional hard material TIM.

However, in the conventional semiconductor package 1, the TIM layer 12 is a fluid and will expand in a molten state at high temperature, so that the TIM layer 12 cannot be stably laid on the inactive surface 11b of the semiconductor chip 11 and thus will overflow onto the packaging substrate 10, causing insufficient TIM between the inactive surface 11b of the semiconductor chip 11 and the top sheet 130 of the heat sink 13. As a result, the heat dissipation of the semiconductor chip 11 is insufficient, so that the semiconductor package 1 is prone to accumulate heat, thereby causing overheating of the semiconductor package 1 and damage to electronic products.

Therefore, how to overcome the aforementioned drawbacks of the prior art has become an urgent issue to be addressed at present.

### SUMMARY

In view of the various shortcomings of the prior art, the present disclosure provides an electronic package, the electronic package comprises: a carrier structure having a circuit layer; an electronic component disposed on the carrier structure and electrically connected to the circuit layer; a heat sink disposed on the carrier structure and covering the electronic component, wherein the heat sink has at least one opening, and a portion of a surface of the electronic component is exposed from the opening; a heat dissipation material formed in the opening and in contact with the electronic component; and a heat dissipation lid disposed on the opening and covering the heat dissipation material.

The present disclosure also provides a method of manufacturing an electronic package, the method comprises: providing a carrier structure with a circuit layer; disposing at least one electronic component on the carrier structure, wherein the electronic component is electrically connected to the circuit layer; disposing a heat sink on the carrier structure to cover the electronic component, wherein the heat sink has at least one opening, and a portion of a surface of the electronic component is exposed from the opening; forming a heat dissipation material in the opening, wherein the heat dissipation material is in contact with the electronic component; and disposing a heat dissipation lid on the opening to cover the heat dissipation material.

The present disclosure further provides a method of manufacturing an electronic package, the method comprises: providing a heat dissipation structure comprising a heat dissipation lid and a heat sink stacked on each other, wherein the heat sink has at least one opening to expose the heat dissipation lid; accommodating a heat dissipation material in the opening on the heat dissipation lid; and disposing a carrier structure with a circuit layer on the heat sink, wherein the carrier structure and the heat sink have an electronic component disposed therebetween, and the electronic component is electrically connected to the circuit layer and in contact with the heat dissipation material.

In the aforementioned electronic package and two methods, the electronic component is electrically connected to the circuit layer via a plurality of conductive bumps.

In the aforementioned electronic package and two methods, the heat dissipation material is served as a thermal interface material.

In the aforementioned electronic package and two methods, the heat dissipation material is in a liquid state.

In the aforementioned electronic package and two methods, the heat sink comprises a sheet-shaped heat dissipation body with the opening and a plurality of supporting legs erected on the heat dissipation body, such that the heat dissipation body accommodates the heat dissipation material by the opening, and the supporting legs are disposed on the carrier structure.

In the aforementioned electronic package and two methods, the heat dissipation lid and the heat sink are stacked and in contact with each other.

In the aforementioned electronic package and two methods, the heat dissipation lid is adhered on the heat sink.

In the aforementioned electronic package and two methods, the heat dissipation lid has at least one through hole communicating with the opening.

In the aforementioned electronic package and two methods, the heat dissipation lid and the heat sink are integrally formed.

As can be seen from the above, in the electronic package and the manufacturing method thereof according to the present disclosure, by the design of the opening and the heat dissipation lid, the flow range of the heat dissipation material is limited to avoid the loss of the heat dissipation material. Hence, compared to the prior art, the electronic package of the present disclosure can prevent the electronic component from having the problem of insufficient heat dissipation due to the loss of the heat dissipation material.

Moreover, the manufacturing method of the present disclosure can use existing materials, processes and machines without adding new processes and materials or purchasing new equipment. Hence, the manufacturing method of the present disclosure can effectively control the cost of the processes, so that the electronic package of the present disclosure is economical.

### BRIEF DESCRIPTION OF THE DRAWINGS

FIG. 1 is a schematic cross-sectional view of a conventional semiconductor package.

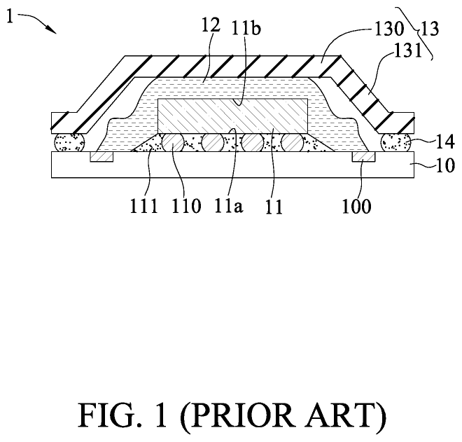

FIG. 2A to FIG. 2D are schematic cross-sectional views illustrating a method of manufacturing an electronic package according to a first embodiment of the present disclosure.

FIG. 3A and FIG. 3B are schematic partial perspective views of FIG. 2D.

FIG. 4A is a schematic cross-sectional view illustrating another aspect of FIG. 2D.

FIG. 4B is a schematic partial perspective view of FIG. 4A.

FIG. 5A to FIG. 5B are schematic cross-sectional views illustrating a method of manufacturing the electronic package according to a second embodiment of the present disclosure.

FIG. 6 is a schematic cross-sectional view illustrating another aspect of FIG. 5A.

### DETAILED DESCRIPTION

The following describes the implementation of the present disclosure with examples. Those familiar with the art can easily understand the other advantages and effects of the present disclosure from the content disclosed in this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

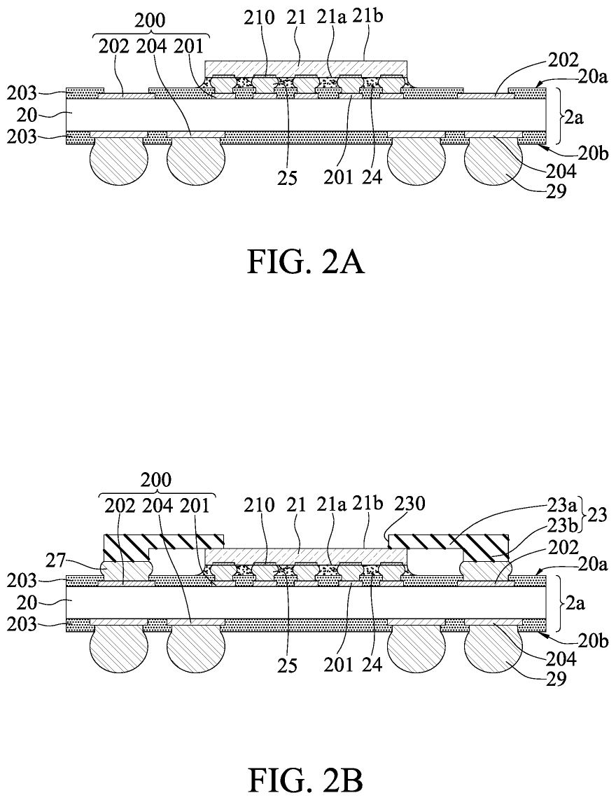

FIG. 2A to FIG. 2D are schematic cross-sectional views illustrating a method of manufacturing an electronic package 2 according to a first embodiment of the present disclosure.

As shown in FIG. 2A, a carrier structure 2a is provided and has a first side 20a and a second side 20b opposing the first side 20a, and at least one electronic component 21 is disposed on the first side 20a of the carrier structure 2a.

The carrier structure 2a can be a packaging substrate with a core layer and a circuit portion or a coreless circuit structure.

In an embodiment, the carrier structure 2a comprises a dielectric body 20 and a circuit layer 200 bonded to the dielectric body 20, such as a fan-out redistribution layer (RDL) specification. For instance, the first side 20a of the carrier structure 2a is used as a chip mounting side for carrying the electronic component 21, and the second side 20b of the carrier structure 2a is used as a ball placement side to place a plurality of conductive components 29 such as solder balls on the second side 20b for connecting to an electronic device (not shown) such as a circuit board.

Moreover, the circuit layer 200 on the first side 20a comprises a plurality of external pads 202 and a plurality of electrical contact pads 201, and the circuit layer 200 on the second side 20b comprises a plurality of ball placement pads 204 bonded to the conductive components 29. Further, an insulating protective layer 203 such as a solder-resist layer is formed on the first side 20a and the second side 20b respectively, so that the external pads 202 and the electrical contact pads 201 on the first side 20a and the ball placement pads 204 on the second side 20b are exposed from the insulating protective layer 203 respectively.

It should be understood that the carrier structure 2a can also be other carrier units for carrying chips, such as a silicon interposer, but not limited to the above.

The electronic component 21 is an active element, a passive element, or a combination of the active element and the passive element. The active element is such as a semiconductor chip, and the passive element is such as a resistor, a capacitor, or an inductor.

In an embodiment, the electronic component 21 is a semiconductor chip and has an active surface 21a and an inactive surface 21b opposing the active surface 21a, and a plurality of electrode pads 210 are formed on the active surface 21a, so that the electrode pads 210 are bonded with and electrically connected to the electrical contact pads 201 of the carrier structure 2a by means of flip-chip via a plurality of conductive bumps 25 such as solder materials, and then an encapsulation layer 24 such as an underfill is filled and formed between the first side 20a of the carrier structure 2a and the active surface 21a of the electronic component 21 to cover the conductive bumps 25.

In other embodiments, the electronic component 21 can also be electrically connected to the electrical contact pads 201 of the carrier structure 2a by means of wire-bonding via a plurality of bonding wires (not shown); alternatively, the electronic component 21 can be directly in contact with the electrical contact pads 201 of the carrier structure 2a.

It should be understood that the ways in which the electronic component 21 is electrically connected to the carrier structure 2a are various, and the required type and quantity of the electronic component 21 that can be disposed on the carrier structure 2a are not limited to the above.

As shown in FIG. 2B, a heat sink 23 with an opening 230 is disposed on the inactive surface 21b of the electronic component 21, and the inactive surface 21b is exposed from the opening 230.

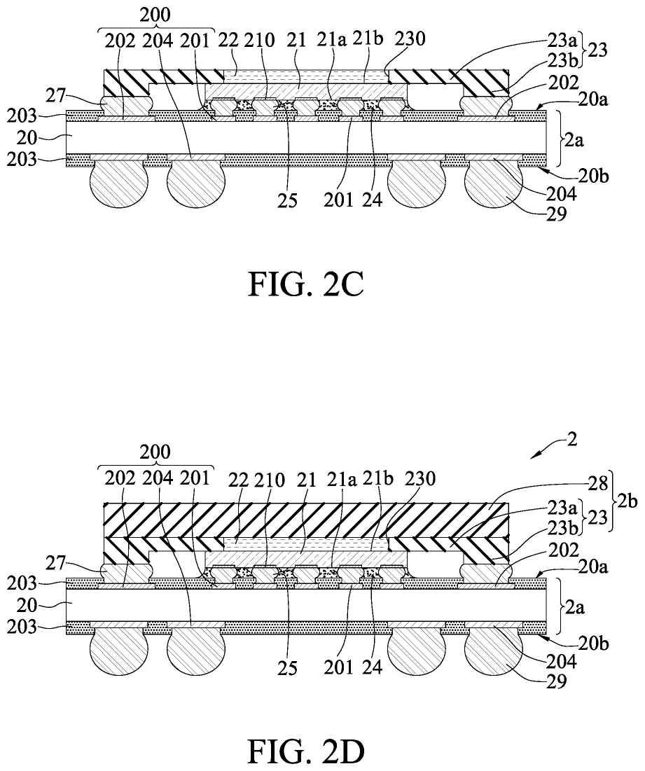

In an embodiment, the heat sink 23 is a metal frame made of such as copper material, as shown in FIG. 3A, the heat sink 23 comprises a sheet-shaped heat dissipation body 23a with the opening 230 and a plurality of supporting legs 23b erected on the heat dissipation body 23a, such that the heat dissipation body 23a is in contact with the inactive surface 21b, and the supporting legs 23b are bonded onto the external pads 202 via a bonding layer 27 made of such as a conductive paste or an insulating glue.

As shown in FIG. 2C, a heat dissipation material 22 is formed in the opening 230, so that the heat dissipation material 22 is in contact with the inactive surface 21b of the electronic component 21.

In an embodiment, the heat dissipation material 22 has a high thermal conductivity of about 30-80 W·m⁻¹·K⁻¹ and serves as a thermal interface material (TIM). For instance, the heat dissipation material 22 is a fluid in a liquid state, such as liquid metal, solder material, silicon glue, ultraviolet (UV) glue, or other molten materials, wherein the liquid metal is pure and does not contain glue materials. It should be understood that there are various kinds of fluid TIMs, but not limited to the above.

As shown in FIG. 2D, a heat dissipation lid 28 is disposed on the heat dissipation body 23a to seal the opening 230, wherein the heat sink 23 and the heat dissipation lid 28 can be regarded as a heat dissipation structure 2b.

In an embodiment, the heat dissipation lid 28 is a metal sheet body made of copper material and has no holes, as shown in FIG. 3B, and the heat dissipation lid 28 and the heat sink 23 can be bonded/adhered together via a glue material (not shown).

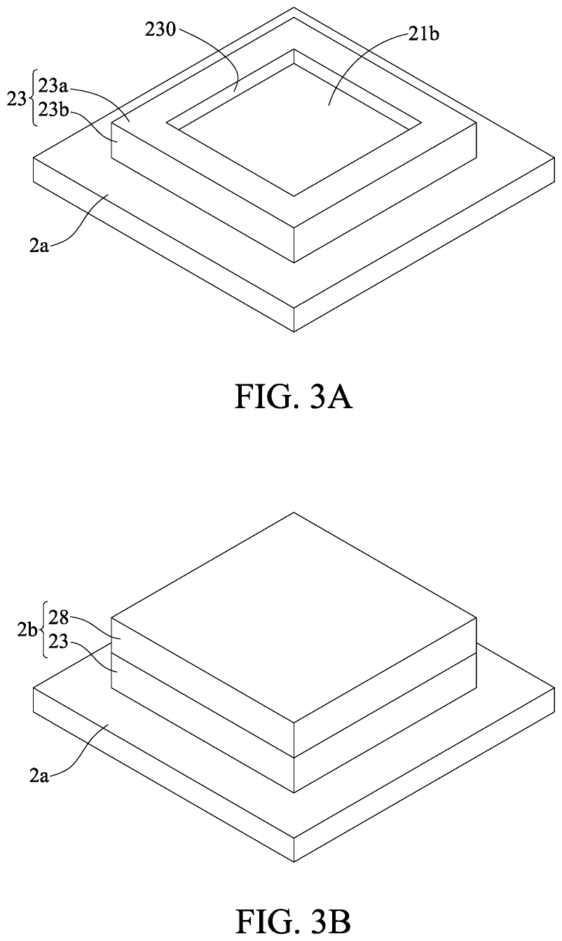

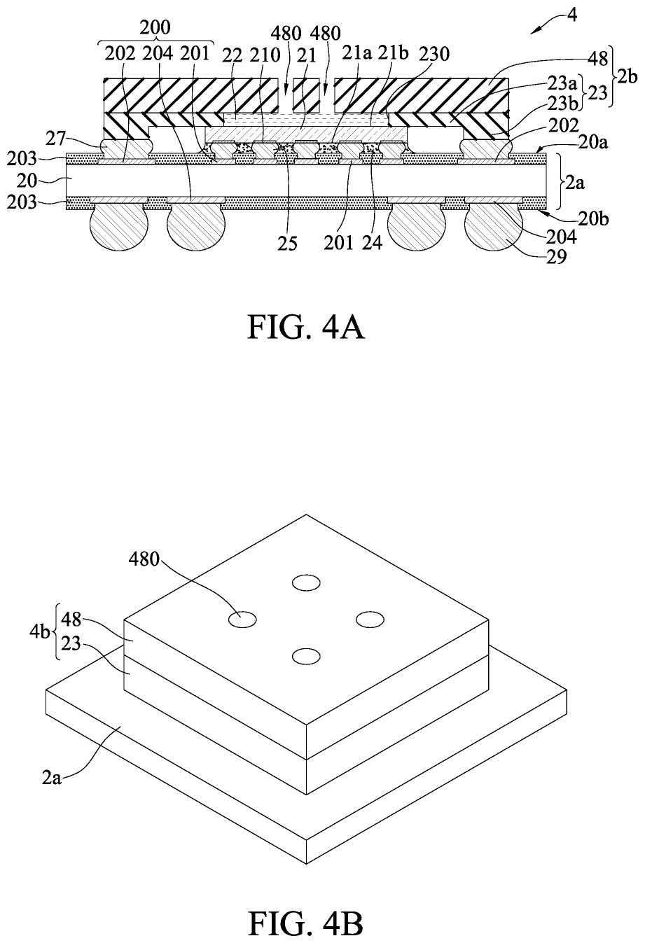

In another embodiment, in an electronic package 4 shown in FIG. 4A and FIG. 4B, at least one through hole 480 penetrating through a heat dissipation lid 48 and in communication with the opening 230 can be formed in the heat dissipation lid 48, so as to facilitate the accommodation of the heat dissipation material 22. It should be understood that if the dimension of the through hole 480 is appropriate, the heat dissipation material 22 will not flow out of a heat dissipation structure 4b due to viscosity or liquid cohesion factors.

Therefore, in the manufacturing method of the present disclosure, the flow range of the heat dissipation material 22 (or liquid metal) can be limited via the opening 230, and the heat dissipation lid 28 seals the heat dissipation material 22 (or liquid metal) in the opening 230 to avoid the loss of the heat dissipation material 22 (or liquid metal). Hence, compared to the prior art, the electronic package 2, 4 of the present disclosure can prevent the electronic component 21 from having the problem of insufficient heat dissipation due to the loss of the heat dissipation material 22 (or liquid metal).

Furthermore, the design of the through hole 480 enables the heat dissipation material 22 (or liquid metal) to exhaust and/or release pressure toward the through hole 480, so problems due to the expansion of the heat dissipation material 22 (or liquid metal) in a high temperature can be avoided (e.g., the expansion of the heat dissipation material 22 [or liquid metal] in a high temperature may cause the heat dissipation material 22 [or liquid metal] to be pressured and bleed from the interface between the heat sink 23 and the electronic component 21 [or the heat dissipation lid 48] or may cause the explosion or delamination of the heat sink 23 [or the heat dissipation lid 48]).

In addition, the manufacturing method of the present disclosure can use existing materials, processes and machines without adding new processes and materials or purchasing new equipment. Hence, the manufacturing method of the present disclosure can effectively control the cost of the processes, so that the electronic package 2, 4 of the present disclosure is economical.

Moreover, if the heat dissipation material 22 is in a liquid state at room temperature in the beginning of the manufacturing process, the method of filling the heat dissipation material 22 will be simpler during the manufacturing process and will not cause the problem of random flow.

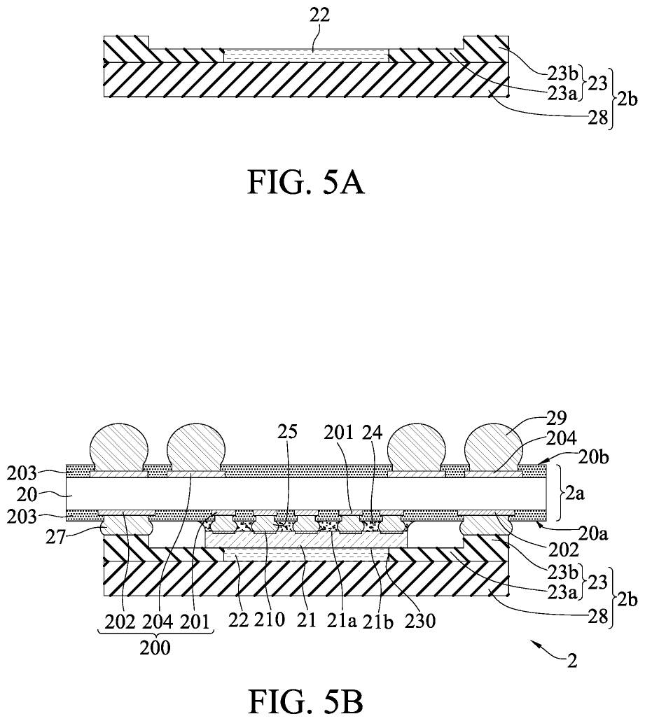

FIG. 5A to FIG. 5B are schematic cross-sectional views illustrating a method of manufacturing the electronic package 2 according to a second embodiment of the present disclosure. The difference between the second embodiment and the first embodiment lies in the manufacturing process sequence, thus only the differences will be described below.

As shown in FIG. 5A, the heat dissipation structure 2b is provided and comprises the heat dissipation lid 28 and the heat sink 23 stacked on each other, wherein the heat dissipation lid 28 is served as a carrier board, and the heat sink 23 has at least one opening 230 to expose the heat dissipation lid 28. Then, the heat dissipation material 22 is accommodated in the opening 230 on the heat dissipation lid 28.

In an embodiment, the heat dissipation lid 28 and the heat sink 23 can be bonded together via a glue material (not shown).

Furthermore, the heat dissipation lid 48 with the through hole 480 can be used as a carrier board, and if the dimension of the through hole 480 is appropriate, the heat dissipation material 22 will not flow out of the heat dissipation structure 4b due to viscosity or liquid cohesion factors.

As shown in FIG. 5B, the carrier structure 2a with the circuit layer 200 is disposed on the heat sink 23, and at least one electronic component 21 is disposed between the carrier structure 2a and the heat sink 23, such that the electronic component 21 is electrically connected to the circuit layer 200 and is in contact with the heat dissipation material 22.

In an embodiment, the electronic component 21 can firstly be disposed on the first side 20a of the carrier structure 2a, and then the carrier structure 2a with the electronic component 21 is disposed on the supporting legs 23b of the heat sink 23, so that the electronic component 21 is in contact with and abuts on the heat dissipation body 23a and the heat dissipation material 22.

In another embodiment, the electronic component 21 can firstly be disposed on the heat dissipation body 23a and the heat dissipation material 22, and then the carrier structure 2a is connected with the electronic component 21 via the first side 20a and is bonded onto the supporting legs 23b of the heat sink 23.

In addition, in the subsequent processes, the plurality of conductive components 29 can be formed on the second side 20b of the carrier structure 2a.

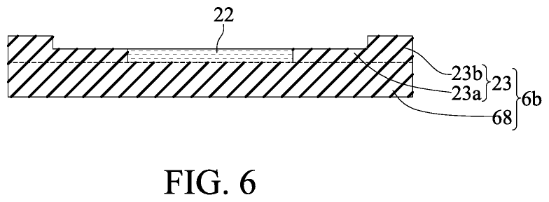

It should be understood that since the heat dissipation lid 28 can be served as a carrier board, thus a heat dissipation lid 68 and the heat sink 23 can be formed integrally, as shown in FIG. 6, so that a heat dissipation structure 6b can be manufactured without using a pasting method, thus the cost of a glue material for bonding the heat dissipation lid 68 and the heat sink 23 can be saved.

Therefore, in the manufacturing method of the present disclosure, the heat dissipation structure 2b, 6b can be served as a carrier, so that the electronic package 2, 4 can be manufactured.

The present disclosure provides an electronic package 2, 4, comprising: a carrier structure 2a having a circuit layer 200, at least one electronic component 21 disposed on the carrier structure 2a and electrically connected to the circuit layer 200, a heat sink 23 disposed on the carrier structure 2a and covering the electronic component 21, a heat dissipation material 22 in contact with the electronic component 21, and a heat dissipation lid 28, 48, 68 covering the heat dissipation material 22.

The heat sink 23 has at least one opening 230, such that a portion of a surface of the electronic component 21 is exposed from the opening 230.

The heat dissipation material 22 is formed in the opening 230.

The heat dissipation lid 28, 48, 68 is disposed on the opening 230.

In an embodiment, the electronic component 21 is electrically connected to the circuit layer 200 via a plurality of conductive bumps 25.

In an embodiment, the heat dissipation material 22 is served as a thermal interface material (TIM).

In an embodiment, the heat dissipation material 22 is in a liquid state.

In an embodiment, the heat sink 23 comprises a sheet-shaped heat dissipation body 23a with the opening 230 and a plurality of supporting legs 23b erected on the heat dissipation body 23a, such that the heat dissipation body 23a accommodates the heat dissipation material 22 via the opening 230, and the supporting legs 23b are disposed on the carrier structure 2a.

In an embodiment, a heat dissipation lid 48 has at least one through hole 480 communicating with the opening 230.

In an embodiment, the heat dissipation lid 68 and the heat sink 23 are formed integrally.

To sum up, in the electronic package and the manufacturing method thereof according to the present disclosure, by the design of the opening and the heat dissipation lid, the flow range of the heat dissipation material is limited to avoid the loss of the heat dissipation material. Hence, the electronic package of the present disclosure can prevent the electronic component from having the problem of insufficient heat dissipation due to the loss of the heat dissipation material.

Besides, the manufacturing method of the present disclosure can use existing materials, processes and machines without adding new processes and materials or purchasing new equipment. Hence, the manufacturing method of the present disclosure can effectively control the cost of the processes, so that the electronic package of the present disclosure is economical.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure having a circuit layer;
an electronic component disposed on the carrier structure and electrically connected to the circuit layer;
a heat sink disposed on the carrier structure and covering the electronic component, wherein the heat sink has at least one opening, and a portion of a surface of the electronic component is exposed from the opening;
a heat dissipation material formed in the opening and in contact with the electronic component; and
a heat dissipation lid disposed on the opening and covering the heat dissipation material.

2. The electronic package of claim 1, wherein the electronic component is electrically connected to the circuit layer via a plurality of conductive bumps.

3. The electronic package of claim 1, wherein the heat dissipation material is served as a thermal interface material.

4. The electronic package of claim 1, wherein the heat dissipation material is in a liquid state.

5. The electronic package of claim 1, wherein the heat sink comprises a sheet-shaped heat dissipation body with the opening and a plurality of supporting legs erected on the heat dissipation body, such that the heat dissipation body accommodates the heat dissipation material by the opening, and the supporting legs are disposed on the carrier structure.

6. The electronic package of claim 1, wherein the heat dissipation lid and the heat sink are stacked and in contact with each other.

7. The electronic package of claim 1, wherein the heat dissipation lid is adhered on the heat sink.

8. The electronic package of claim 1, wherein the heat dissipation lid has at least one through hole communicating with the opening.

9. The electronic package of claim 1, wherein the heat dissipation lid and the heat sink are integrally formed.

10. A method of manufacturing an electronic package, comprising:
providing a carrier structure with a circuit layer;
disposing at least one electronic component on the carrier structure, wherein the electronic component is electrically connected to the circuit layer;
disposing a heat sink on the carrier structure to cover the electronic component, wherein the heat sink has at least one opening, and a portion of a surface of the electronic component is exposed from the opening;
forming a heat dissipation material in the opening, wherein the heat dissipation material is in contact with the electronic component; and
disposing a heat dissipation lid on the opening to cover the heat dissipation material.

11. The method of claim 10, wherein the electronic component is electrically connected to the circuit layer via a plurality of conductive bumps.

12. The method of claim 10, wherein the heat dissipation material is served as a thermal interface material.

13. The method of claim 10, wherein the heat dissipation material is in a liquid state.

14. The method of claim 10, wherein the heat sink comprises a sheet-shaped heat dissipation body with the opening and a plurality of supporting legs erected on the heat dissipation body, such that the heat dissipation body accommodates the heat dissipation material by the opening, and the supporting legs are disposed on the carrier structure.

15. The method of claim 10, wherein the heat dissipation lid and the heat sink are stacked and in contact with each other.

16. The method of claim 10, wherein the heat dissipation lid is adhered on the heat sink.

17. The method of claim 10, wherein the heat dissipation lid has at least one through hole communicating with the opening.

18. The method of claim 10, wherein the heat dissipation lid and the heat sink are integrally formed.

19. A method of manufacturing an electronic package, comprising:
providing a heat dissipation structure comprising a heat dissipation lid and a heat sink stacked on each other, wherein the heat sink has at least one opening to expose the heat dissipation lid;
accommodating a heat dissipation material in the opening on the heat dissipation lid; and
disposing a carrier structure with a circuit layer on the heat sink, wherein the carrier structure and the heat sink have an electronic component disposed therebetween, and the electronic component is electrically connected to the circuit layer and in contact with the heat dissipation material.

20. The method of claim 19, wherein the electronic component is electrically connected to the circuit layer via a plurality of conductive bumps.

21. The method of claim 19, wherein the heat dissipation material is served as a thermal interface material.

22. The method of claim 19, wherein the heat dissipation material is in a liquid state.

23. The method of claim 19, wherein the heat sink comprises a sheet-shaped heat dissipation body with the opening and a plurality of supporting legs erected on the heat dissipation body, such that the heat dissipation body accommodates the heat dissipation material by the opening, and the supporting legs are disposed on the carrier structure.

24. The method of claim 19, wherein the heat dissipation lid and the heat sink are stacked and in contact with each other.

25. The method of claim 19, wherein the heat dissipation lid is adhered on the heat sink.

26. The method of claim 19, wherein the heat dissipation lid has at least one through hole communicating with the opening.

27. The method of claim 19, wherein the heat dissipation lid and the heat sink are integrally formed.
